(19) United States
(12) Patent Application Publication
(10) Pub. No.: US 2007/0079220 A1
(43) Pub. Date: Apr. 5, 2007

(54) Audio player

(76) Inventors: Satoshi Shinzaki, Osaka (JP); Seigo Suguta, Osaka (JP); Takeshi Fujita, Osaka (JP)

Correspondence Address: MCDERMOTT WILL & EMERY LLP, 600 13TH STREET, N.W., WASHINGTON, DC, 20005-3096, US

(21) Appl. No.: 11/499,684

(22) Filed: Aug. 7, 2006

(30) Foreign Application Priority Data
Sep. 15, 2005 (JP) 2005-268922

(51) Int. Cl. G11C 29/00

(52) U.S. Cl. 714/769

(57) ABSTRACT

A reproduction section includes a Q data processing section and an audio processing section. A control section transmits Q data replacement method instruction information, a Q data initial value, Q data output method instruction information which are given from the outside to the Q data processing section. When an error exists in Q data received from the outside, basically, the Q data processing section replaces the Q data with Q data which does not contain an error and outputs the error-free Q data. A plurality of error processing methods to be used when an error exists in Q data are prepared so that which one of the methods can be selected according to the instruction information.

### BACKGROUND OF THE INVENTION

The present invention relates to digital signal processing techniques in a broad sense, and particularly relates to an audio player for performing error-concealment when an error occurs in Q data to be output in reproducing a music CD.

In a music CD, Q data which is different data from audio data is recorded in a sub-coded Q channel. Such Q data is used for reproduction time display and pause detection in dubbing. Conventionally, a system in which in reproducing a music CD, audio data and Q data are synchronized and then output has been known (see Japanese Laid-Open Patent Publication No. 2001-155432).

Assume that an error exists in Q data output when a music CD is reproduced. If the Q data is output as it is, problems arise. For example, reproduction time display momentarily indicates an abnormal value or, during dubbing, depending on external equipment connected thereto, pause detection is wrongly performed and thus a track expected to be dubbed is recorded as an unwanted track.

To avoid such problems, when an error in Q data is detected, it is preferable that the Q data is replaced with data which does not contain an error and then is output. However, a method for outputting Q data depends on product specification, and thus there arises another problem. That is, if an audio player section is incorporated in various different systems, which error processing method is used can not be uniquely determined.

### SUMMARY OF THE INVENTION

It is therefore an object of the present invention to solve the above-described problems and provide an audio player with general versatility which includes an interface for allowing specifying, for a control section and a reproduction section, a processing method and an output method when an error exists in Q data and thus does not depend on an incorporated system.

To achieve the above-described object, an audio player according to the present invention is configured so as to include a plurality of methods for replacing, when an error exists in Q data in reproducing a music CD, the Q data with another Q data which does not contain an error, or so that as a method for outputting Q data when an error occurs, either one of a method for outputting received data as it is or a method for outputting replaced data can be externally selected.

With the audio player of the present invention, even if Q data contains an error, abnormal display of a reproduction time and misrecording in dubbing can be prevented. Moreover, by making it possible to externally select a Q data output method to be used when an error occurs, an audio player with general versatility which does not depend on an incorporated system can be provided.

### BRIEF DESCRIPTION OF THE DRAWINGS

FIG. 1 is a configuration drawing of Q data.

FIG. 2 is a detailed configuration drawing of a DATA region in FIG. 1.

FIG. 3 is a block diagram illustrating an exemplary configuration of an audio player according to the present invention.

FIG. 4 is a flowchart showing respective operations of a Q data processing section in FIG. 3.

FIG. 5 is a flowchart showing respective detailed operations of Q data error processing in FIG. 4.

### DESCRIPTION OF THE PREFERRED EMBODIMENTS

Hereafter, embodiments of the present invention will be described with reference to the accompanying drawings.

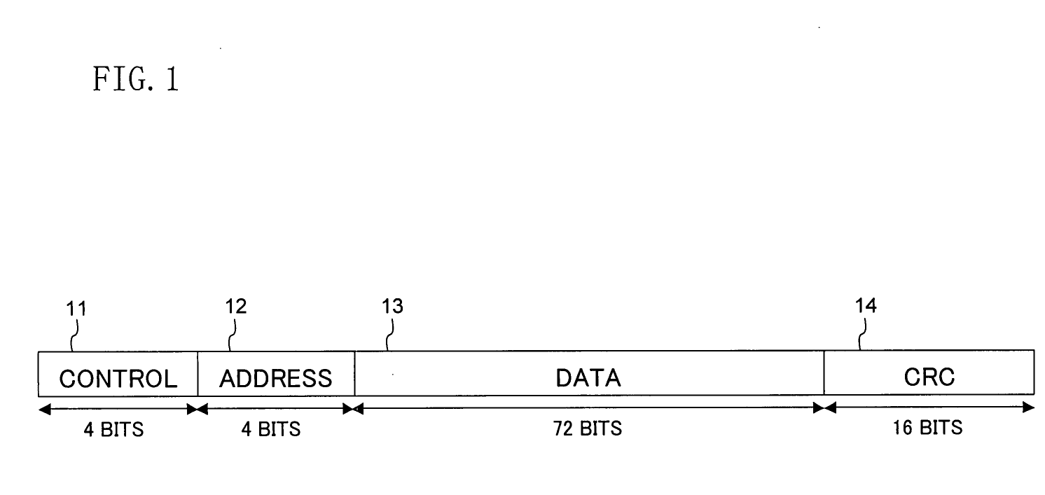

FIG. 1 is a drawing illustrating a configuration of Q data recorded on a music CD. The Q data includes a CONTROL region 11, an ADDRESS region 12, a DATA region 13 and a CRC region 14.

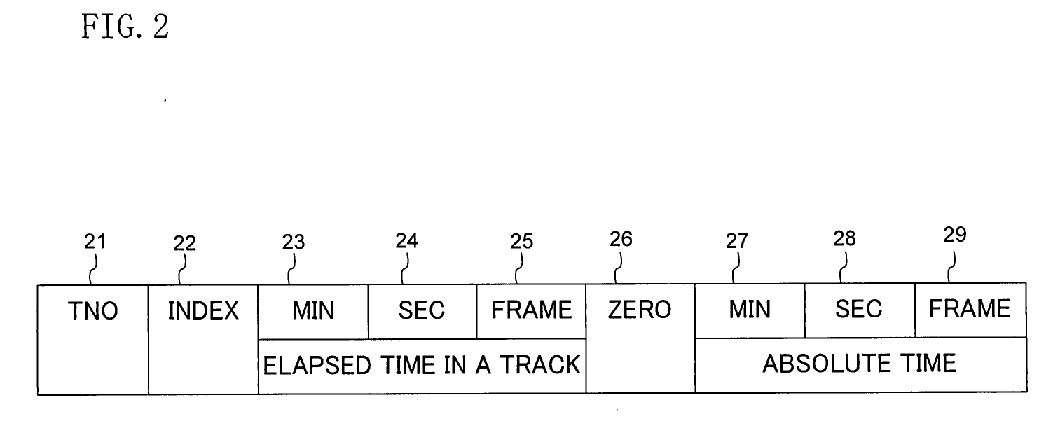

FIG. 2 is a drawing illustrating a configuration of the DATA region 13 of the Q data. The DATA region 13 includes a track number (TNO) section 21, an INDEX section 22, an elapsed time (MIN) section 23, an elapsed time (SEC) section 24, an elapsed time (FRAME) section 25, a ZERO section 26, an absolute time (MIN) section 27, an absolute time (SEC) section 28 and an absolute time (FRAME) section 29.

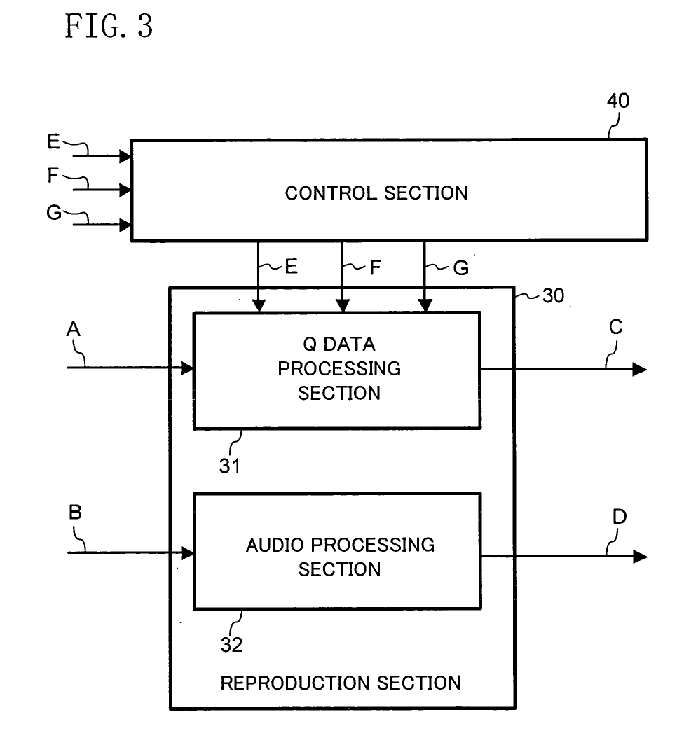

FIG. 3 is a block diagram illustrating an exemplary configuration of an audio player according to the present invention. The audio player of FIG. 3 includes broadly two parts, i.e., a control section 30 and a reproduction section 40.

The reproduction section 30 includes a Q data processing section 31 and an audio processing section 32. When an error exists in the Q data A received from the outside, the Q data processing section 31 basically replaces the Q data A with Q data C which does not contain an error and then outputs the Q data C. Thus, abnormal reproduction time display and misrecording in dubbing can be prevented. The audio processing section 32 decodes audio data B received from the outside and then outputs decoded audio data D. The output Q data C is synchronized with audio data D.

A control section 40 has the function of receiving from the outside Q data replacement method instruction information E, a Q data initial value F and Q data output method instruction information G and transmitting those information to the Q data processing section 31.

In the audio player of this embodiment, information in the DATA region 13 of FIG. 1 is used for displaying a reproduction time and a truck number. Also, error judgment for Q data is performed using data of the CRC region 14.

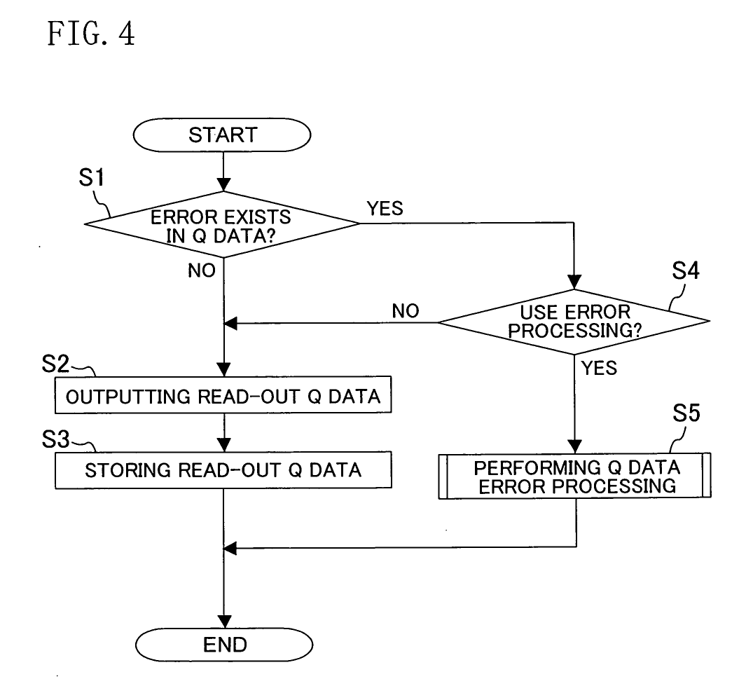

FIG. 4 is a flowchart showing respective operations of the Q data processing section 31 in FIG. 3. First, in Step S1, whether or not an error exists in Q data received from the outside is judged. If no error exists, the Q data processing section 31 outputs the read-out Q data in Step S2 and then stores the read-out Q data in Step S3.

If an error exists in the Q data received from the outside, the processing proceeds from Step S1 to Step S4. In Step S4, a method for outputting the Q data is selected according to the Q data output method instruction information G. Then, if proceeding to Step S2 is selected, the received Q data is output as it is. If proceeding from Step S4 to Step S5 is selected, predetermined Q data error processing is performed. By making it possible to externally select an output method to be used when an error exists in Q data, the audio player of this embodiment can be incorporated in a wide range of systems.

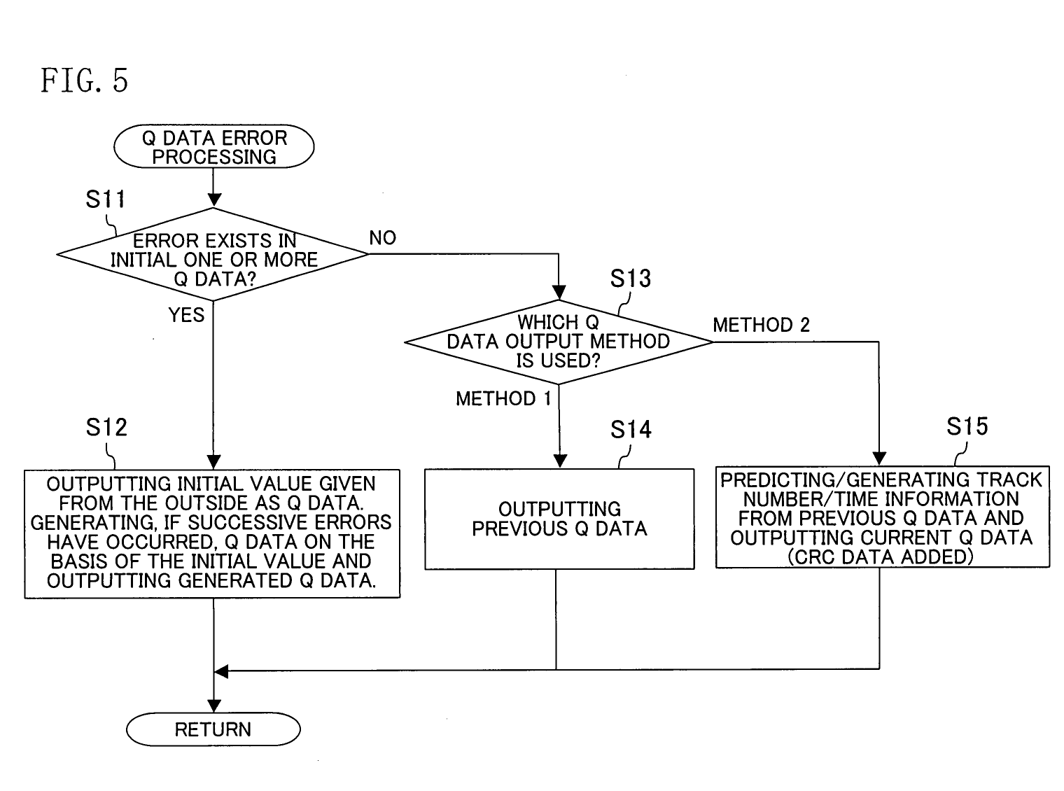

FIG. 5 is a flowchart showing respective detailed operations of the Q data error processing in FIG. 4. First, in Step S11, whether or not an error has occurred in initial one or more of a plurality of Q data is examined. Then, if an error exists in Q data received from the outside and the Q data is initially received data, the processing proceeds to Step S12. In Step S12, a Q data initial value F given from the outside is output as Q data. However, if successive errors have occurred, current Q data is generated on the basis of the initial value F and then the generated current Q data is output. Thus, even if an error exists in initial one or more of the plurality of Q data to which processing such as data replacement with previous Q data and data prediction from previous Q data can not be performed, output of Q data containing abnormal data against an intention of a user of the audio player of this invention can be prevented.

If an error exists in Q data received from the outside but the Q data is not initially received data, the processing proceeds from Step S11 to Step S13. In Step S13, judgment according to the Q data replacement method instruction information E is performed. For example, to which region of the Q data prediction and generation are performed is determined. By making it possible to externally select an output method when an error exists in Q data, the audio player of this embodiment can be incorporated in a wide range of systems.

For example, in Step S14, where “Method 1” is selected, normal Q data used for a previous output is output as Q data for current output. Thus, output of Q data containing abnormal data can be prevented.

In Step S15, where “Method 2” is selected, a track number and time information for current Q data are predicted from previous Q data and current Q data is generated on the basis of the prediction. Then, the generated current Q data is output. Thus, a reproduction time and a track number can be displayed with precision in a relatively simple manner without application of a load to a system. In this case, it is preferable that CRC data calculation for the predicted Q data is performed and a calculation result is output as current Q data. Thus, error-free Q data of which CRC data value is ensured can be output.

As has been described, an audio player according to the present invention is so configured that a plurality of error concealment methods used when an error occurs in Q data are provided and an interface for making it possible to externally set which one of the methods is used. Thus, the audio player can normally perform reproduction and dubbing of a music CD without depending on an incorporated system. Therefore, the audio player is useful as an audio player with general versatility.

What is claimed is:

1. An audio player which has a function of synchronizing Q data with audio data and outputting the synchronized Q data when a music CD is reproduced, the audio player comprising:
a reproduction section; and
a control section for controlling the reproduction section,
wherein the reproduction section includes
an audio processing section for performing audio processing to a received audio data stream, and
a Q data processing section for synchronizing received Q data with audio data and outputting the synchronized Q data, and
wherein when an error exists in the received Q data, the audio player has a function of replacing the received Q data with Q data which does not contain an error in the Q data processing section and outputting the Q data which does not contain an error.

2. The audio player of claim 1, wherein the audio player has, as a method for replacing the received Q data with Q data which does not contain an error when the received Q data contains an error, a function of replacing the received Q data with previous Q data which does not contain an error.

3. The audio player of claim 1, wherein the audio player has, as a method for replacing the received Q data with Q data which does not contain an error when the received Q data contains an error, a function of predicting and generating, from previous Q data which does not contain an error, only a track number and time information in the Q data and outputting the generated Q data as current Q data.

4. The audio player of claim 1, wherein the audio player has, as a method for replacing the received Q data with Q data which does not contain an error when the received Q data contains an error, a function of predicting and generating, from previous Q data which does not contain an error, Q data to be currently output, adding CRC data obtained by performing calculation to the generated Q data and outputting, as current Q data, the obtained Q data in an error-free state.

5. The audio player of claim 1, further comprising an interface for allowing, when the received Q data contains an error, external selection of either one of a plurality of methods used in replacing the received Q data with Q data which does not contain an error.

6. The audio player of claim 1, further comprising an interface for allowing, when an initially received Q data contains an error, external specification of an initial value of the Q data.

7. The audio player of claim 1, wherein the audio player has, as a method for replacing the received Q data with Q data which does not contain an error when each of initial one or more successive Q data contains an error, a function of generating Q data to be currently output on the basis of an initial value of externally specified Q data and outputting the generated Q data.

8. The audio player of claim 1, further comprising an interface for allowing, when the received Q data contains an error, external selection of either one of replacing the received Q data with Q data which does not contain an error and outputting the received Q data as it is.
